(19) United States
(12) Patent Application Publication
(10) Pub. No.: US 2024/0162186 A1
(43) Pub. Date: May 16, 2024

(54) METHOD OF FABRICATING AN ELECTRONIC DEVICE

(71) Applicant: STMicroelectronics (Crolles 2) SAS, Crolles (FR)

(72) Inventors: Sandrine LHOSTIS, Theys (FR); Emilie DELOFFRE, Saint Ismier (FR); Sebastien MERMOZ, Bernin (FR)

(73) Assignee: STMicroelectronics (Crolles 2) SAS, Crolles (FR)

(21) Appl. No.: 18/389,020

(22) Filed: Nov. 13, 2023

(30) Foreign Application Priority Data
Nov. 15, 2022 (FR) 2211871

(51) Int. Cl. H01L 23/00; H01L 23/498

(52) U.S. Cl. CPC H01L 24/89; H01L 23/49827; H01L 24/27; H01L 23/49861; H01L 2224/27522; H01L 2224/80357; H01L 2224/80895; H01L 2924/1431

(57) ABSTRACT

A first wafer includes a first semiconductor layer and first metal contacts on a side of a first surface of the first semiconductor layer. A second wafer includes a second semiconductor layer and second metal contacts on a side of a first surface of the second semiconductor layer. A handle is bonded onto a surface of the second wafer opposite to the second semiconductor layer. The second semiconductor layer is then removed to expose the second metal contacts. A bonding is then performed between the first and second wafers to electrically connect the first metal contacts to the second metal contacts.

### PRIORITY CLAIM

This application claims the priority benefit of French Application for Patent No. 2211871, filed on Nov. 15, 2022, the content of which is hereby incorporated by reference in its entirety to the maximum extent allowable by law.

### TECHNICAL FIELD

The present disclosure generally concerns the field of the fabrication of electronic devices and, in particular, a method of assembly of two structures. It more particularly concerns a method of assembly of two structures by hybrid bonding.

### BACKGROUND

There is a need to improve methods of assembly of at least two structures to overcome the disadvantages, for example in terms of bulk, of through silicon vias or TSVs.

There further is a need to improve known hybrid bonding methods and more particularly methods of hybrid bonding of the front side of a structure with the back side of another structure in a configuration referred to in the art as “Face To Back” (F2B).

There is a need to overcome all or part of the disadvantages of known methods.

### SUMMARY

An embodiment provides a method of assembly of first and second wafers by bonding, comprising the steps of: a) forming a first wafer comprising a first semiconductor layer and first metal contacts on the side of a first surface of the first semiconductor layer; b) forming a second wafer comprising a second semiconductor layer and second metal contacts on the side of a first surface of the second semiconductor layer; c) after step b), transfer and bonding a handle onto the surface of the second wafer opposite to the second semiconductor layer; d) after step c), removing the second semiconductor layer to expose the second metal contacts; and e) after steps a) and d), bonding the first and second wafers to electrically connect the first metal contacts to the second metal contacts.

According to an embodiment, the method comprises, between steps a) and e), activating the surface of the first metal contacts opposite to the first semiconductor layer and, between steps d) and e), activating a surface of the second metal contacts exposed during step d).

According to an embodiment, the two activating steps are carried out during a same step, under vacuum in a same activation chamber.

According to an embodiment, step e) is carried out under vacuum, with no rupture of vacuum with the activating step.

According to an embodiment, the method comprises, between steps b) and c), a step f) of forming a heat-sensitive element on the second wafer.

According to an embodiment, the method comprises, after step a), a step g) of forming an amorphous silicon layer on the first metal contacts.

According to an embodiment, the method comprises, before step b), a step of forming a layer in the second semiconductor layer on the side of the first surface thereof.

According to an embodiment, the handle is inactive.

According to an embodiment, the handle is inactive and comprises a logic circuit.

According to an embodiment, during step c), the handle is bonded to the second wafer by a surface-activated bonding.

According to an embodiment, during step c), the handle is bonded to the second wafer by an adhesive layer, an electric contact being formed via at least one boss formed in the handle.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIGS. 1A-1P show steps of an assembly method according to a first embodiment;

FIGS. 2A-2C show steps of an assembly method according to a second embodiment;

FIGS. 3A-3C show steps of an assembly method according to a third embodiment; and

FIGS. 4A-4G show steps of an assembly method according to a fourth embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, these embodiments describe the assembly of two structures where electronic components have already been formed, only those steps necessary to the forming of the assembly have been described hereafter. The type of electronic components forming the structures targeted by the assembly and the steps of forming of these elements have not been detailed hereafter.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made, unless specified otherwise, to the orientation of the figures.

Unless specified otherwise, the expressions “around”, “approximately”, “substantially” and “in the order of” signify within 10%, and preferably within 5%.

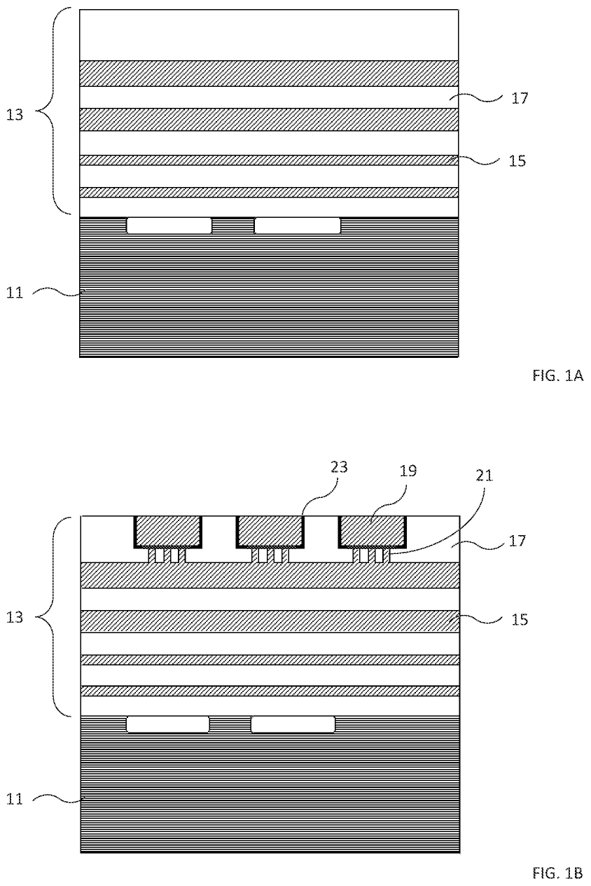

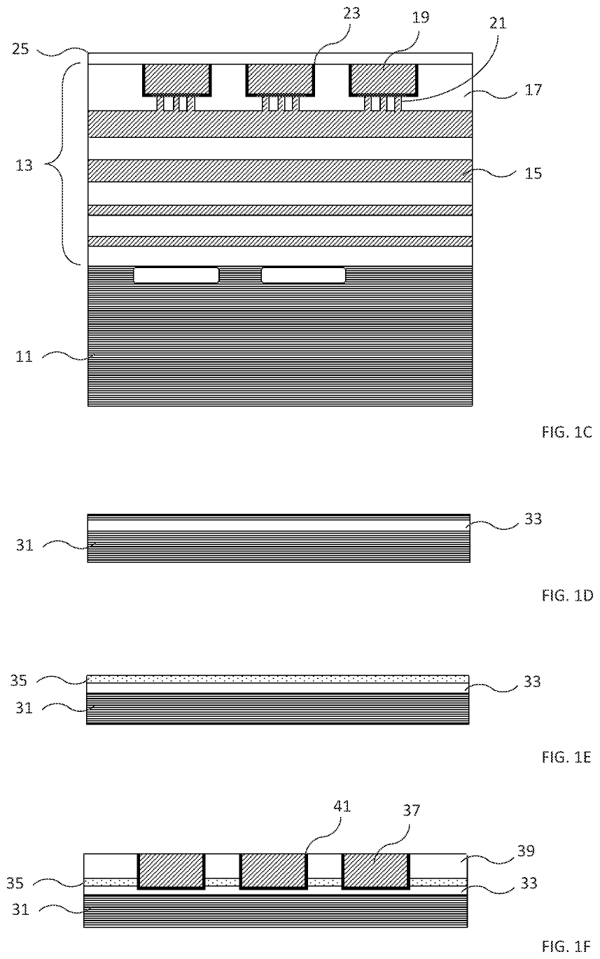

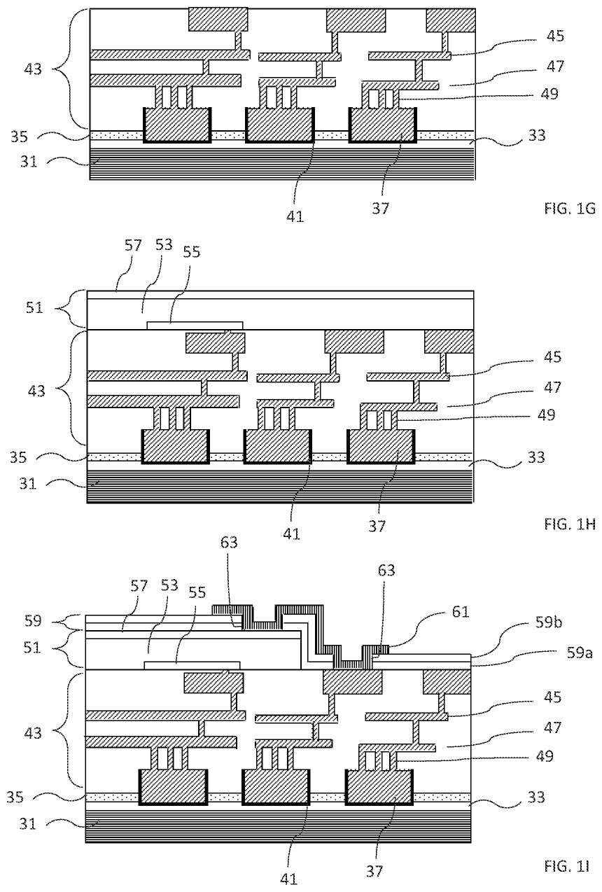

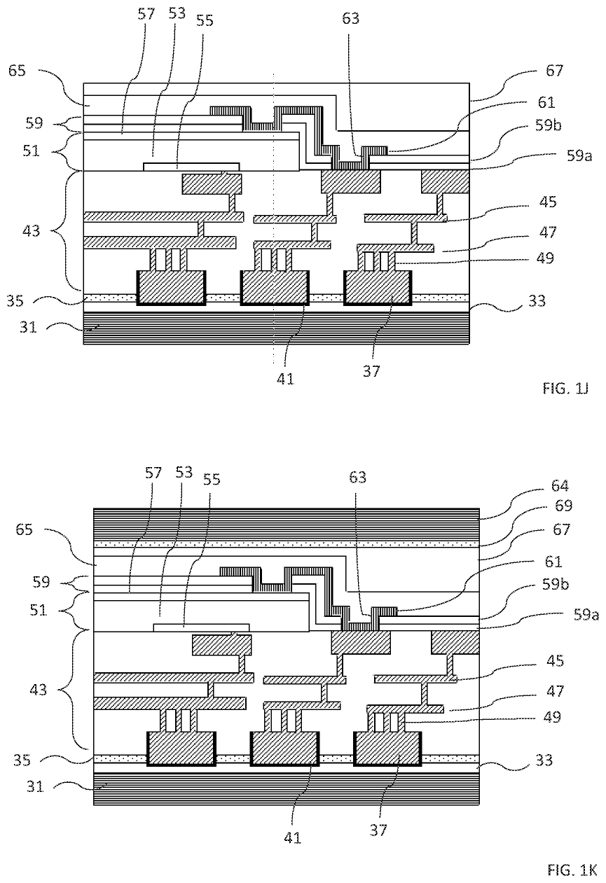

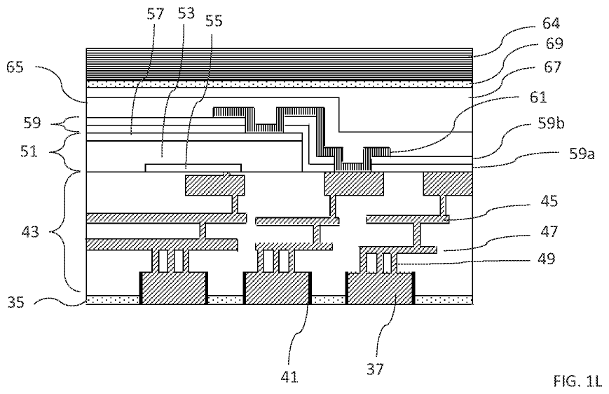

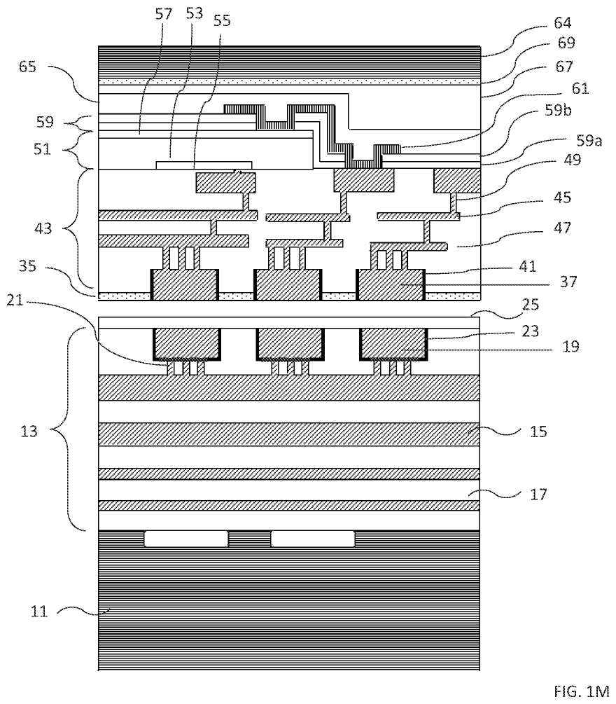

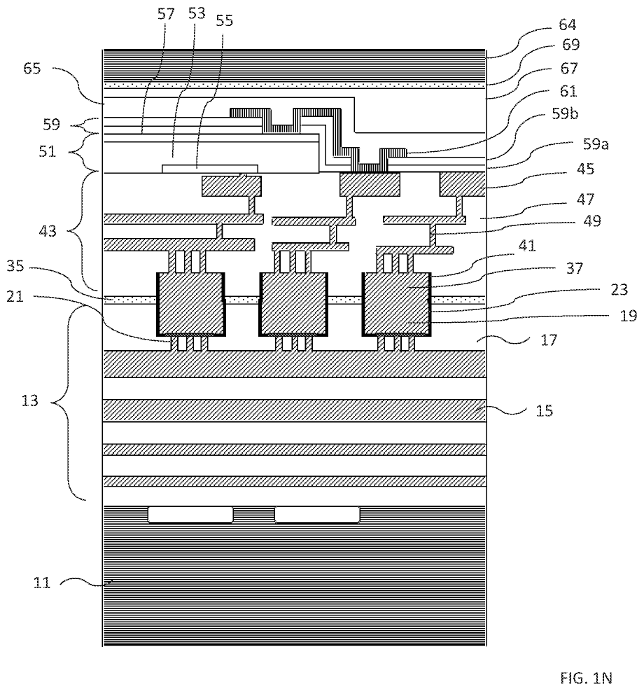

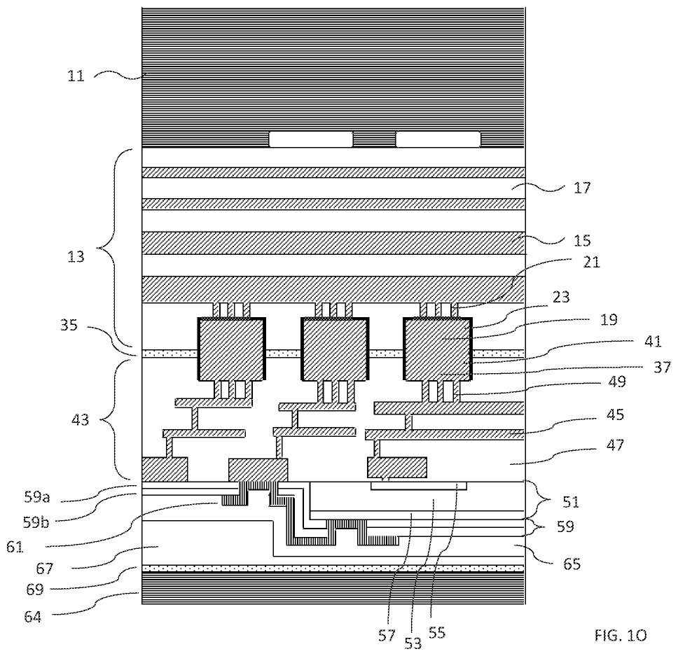

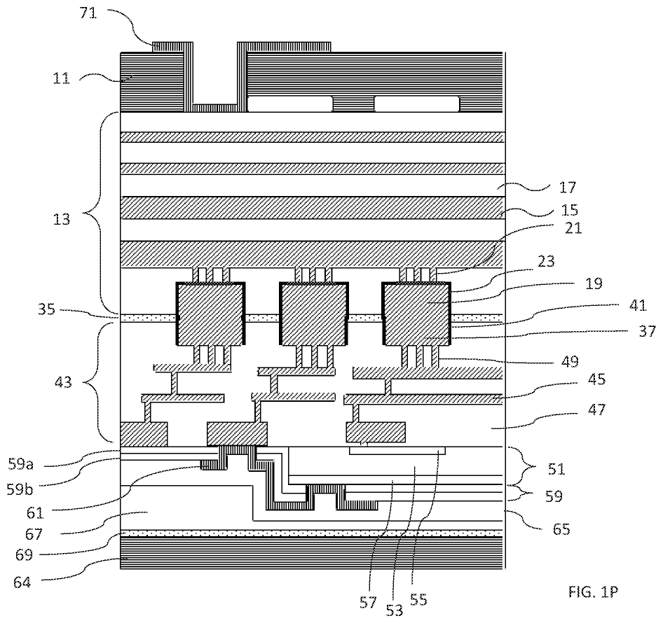

FIGS. 1A-1P show steps of an assembly method according to a first embodiment.

In this embodiment, it is provided to assemble a first structure comprising a logic circuit with a second structure comprising an inactive handle and a heat-sensitive element, that is, an element likely to be degraded under the effect of heat, for example, if it is taken to a temperature higher than or equal to 150° C. or higher than or equal to 200° C.

More particularly, FIGS. 1A to 1C are successive steps of a method of forming the first structure of the assembly.

FIG. 1A illustrates an initial structure comprising, on a first substrate 11 or semiconductor layer, and more particularly on the upper surface of substrate 11, a stack 13 comprising an alternation of conductive tracks 15 and of insulating layers 17. As an example, the initial structure is formed by standard front-end-of-line (FEOL) and back-end-of-line (BEOL) methods. Substrate 11 is, for example, made of a semiconductor material, for example, a semiconductor wafer, for example, made of silicon. As an example, the structure of FIG. 1A comprises electronic components, for example transistors, formed inside and/or on top of substrate 11. Conductive tracks 15 are, for example, made of a conductive material, for example a metallic material. As an example, conductive tracks 15 are made of copper. Insulating layers 17 are, for example, made of an oxide, for example made of silicon dioxide (SiO₂). The structure such as illustrated in FIG. 1A has, for example, a planar upper surface, for example planarized by an insulating upper layer 17. In FIG. 1A, four levels of conductive tracks 15 have been shown, however, in practice, stack 13 may comprise a number of conductive levels different from four, for example greater than four. The conductive tracks 15 of the different levels are, for example, coupled together by conductive vias (not detailed in the drawings) crossing insulating layers 17. Conductive tracks 15 may be connected to electronic components formed inside and/or on top of substrate 11.

FIG. 1B illustrates a structure obtained at the end of a step of forming of first metal connection pads 19 or metal contacts in the structure illustrated in FIG. 1A.

During this step, pads 19 and vias 21 coupling pads 19 to one or a plurality of conductive tracks 15, for example one or a plurality of tracks of the upper conductive level of stack 13, are formed.

Pads 19 are, for example, formed from the upper surface of the structure, in one of the insulating layers 17 of stack 13, for example, the upper insulating layer. As an example, vias 21 and pads 19 are made of copper. Vias 21 and pads 19 may be made of the same material as conductive tracks 15.

As an example, each pad 19 is surrounded with a barrier layer 23. Barrier layer 23 is, for example, formed after the forming of vias 21 and before the forming of pads 19. Barrier layer 23 is then present at the interface between upper insulating layer 17 and each pad 19 on the sides of pad 19 and on the lower surface of pad 19. The barrier layer is, for example, made of a material enabling to form a barrier to the diffusion of copper in the silicon. As an example, barrier layer 23 is made of a material different from copper, for example an electrically-conductive material, for example made of titanium nitride (TiN) or of tantalum nitride (TaN).

After the forming of vias 21 and of pads 19, the upper surface of the structure is, for example, planarized so that pads 19 are flush with the upper surface of stack 13. This planarization step may be performed by chemical mechanical planarization (CMP).

In FIG. 1B, three pads 19 have been shown, however, in practice, the number of pads 19 may be different from three, for example greater than three.

FIG. 1C illustrates a structure obtained at the end of a step of deposition of a layer 25 on the upper surface of the structure illustrated in FIG. 1B.

As an example, layer 25 is made of a non-conductive material. Layer 25 is, for example, made of silicon, for example made of amorphous silicon, and is, for example, non-intentionally doped. Layer 25 has, for example, a thickness in the range from 1 nm to 20 nm, for example in the order of 2 nm.

Layer 25 is, for example, deposited in full wafer fashion, that is it is deposited over the entire surface of the structure. As an example, layer 25 is deposited at a temperature lower than 400° C.

The structure illustrated in FIG. 1C corresponds to the first structure of the assembly, the front side of this structure corresponding to its upper surface in the orientation of FIG. 1C and the back side of this structure corresponding to its lower surface in the orientation of FIG. 1C.

FIGS. 1D to 1K are successive steps of a method of forming the second structure of the assembly.

FIG. 1D illustrates an initial structure corresponding to a second substrate 31 or semiconductor layer, for example a semiconductor wafer. As an example, substrate 31 corresponds to a solid silicon substrate or to the upper silicon layer of a substrate of silicon-on-insulator (SOI) type.

Optionally, substrate 31 comprises a stop layer 33, for example, buried in substrate 31. As an example, stop layer 33 is formed over the entire surface of substrate 31. As an example, stop layer 31 is made of doped silicon or of silicon oxide.

FIG. 1E illustrates a structure obtained at the end of a step of forming of a layer 35 in the structure illustrated in FIG. 1D.

As an example, layer 35 is made of an electrically-insulating or high-resistivity material.

Layer 35 is, for example, made of amorphous silicon, for example formed by amorphization of the upper surface of the structure illustrated in FIG. 1D. Layer 35 is thus formed, with no addition of material, from the structure illustrated in FIG. 1D and more particularly from substrate 31. This forming mode enables layer 35 to have a more significant purity level than a layer formed by deposition of amorphous silicon. Amorphous silicon layer 35 is preferably non-intentionally doped.

As an example, layer 35 has a thickness in the order of a few nanometers, for example a thickness in the range from 1 nm to 20 nm, for example on the order of 2 nm.

Layer 35 is, for example, formed in full wafer fashion, that is it is formed over the entire surface of the structure. Layer 35 is, for example, formed on top of and in contact with stop layer 33.

FIG. 1F illustrates a structure obtained at the end of a step of forming of second metal pads 37 or contacts.

During this step, an insulating layer 39 is deposited on the upper surface of the structure illustrated in FIG. 1E and then pads 37 are formed.

As an example, layer 39 is made of a dielectric material, for example made of an oxide, for example made of silicon dioxide. Layer 39 is, for example, formed in full wafer fashion, that is it is formed over the entire surface of the structure. As an example, layer 39 is formed with a uniform thickness, for example on the order of 500 nm.

The forming of pads 37 comprises a step of forming of openings intended to receive pads 37 followed by a step of filling of the openings. The openings are formed, for example, from the upper surface of layer 39 and emerge, for example, into stop layer 33. Thus, the openings cross layer 39, layer 35, and a portion of layer 33. As an example, pads 37 are formed so that they sink beyond layer 39 across a thickness of a few nanometers, for example, in the range from 2 nm to 250 nm. In the shown example, pads 39 cross layer 35 and emerge and stop in stop layer 33.

As an example, pads 37 are made of the same material as pads 19. As an example, pads 37 are made of copper. Pads 37 have a thickness, for example, in the range from 100 nm to 500 nm, for example on the order of 500 nm.

Similar to what has been described for pads 19 in relation with FIG. 1B, each pad 37 may be surrounded with a barrier layer 41. Barrier layer 41 is then present at the interface between layers 39, 33, and 35 and each pad 37. Barrier layer 41 is, for example, made of a material enabling to form a barrier to the diffusion of copper in the silicon. As an example, barrier layer 41 is made of a material different from copper, for example made of a conductive material, for example made of titanium nitride (TiN) or tantalum nitride (TaN).

After the forming of pads 37, the upper surface of the structure is, for example, planarized so that pads 37 are flush with the upper surface of layer 39. This planarization step may be carried out by chemical mechanical polishing (CMP).

Similar to what has been described in relation with FIG. 1B, three pads 37 have been shown in FIG. 1F. However, in practice, the number of pads 37 may be different from three, for example greater than three. As an example, pads 19 and 37 being intended to be assembled to each other, the number of pads 19 is identical to the number of pads 37.

FIG. 1G illustrates a structure obtained at the end of a step of forming of a stack 43 of metallization levels on the upper surface of the structure illustrated in FIG. 1F.

During this step, a stack of metallization levels 45 and of insulating layers 49 alternated on the upper surface of the structure illustrated in FIG. 1F is, for example, formed.

As an example, stack 43 comprises conductive vias 49 arranged vertically in the orientation of FIG. 1G, coupling metallization levels 45 by crossing insulating layers 47. As an example, metallization levels 45 and vias 49 are made of a metallic material, for example made of copper. Insulating layers 47 are, for example, made of the same material as layer 39, for example made of silicon dioxide.

Stack 43 and more particularly levels 45 are, for example, formed so that the thicker levels 45 are formed first. The described embodiments are however not limited to this specific case.

In FIG. 1G, three metallization levels 45 have been shown, however, in practice, the number of levels may be greater than three.

At the end of this step, metallization levels 45 are, for example, flush with the upper surface of the structure. For this purpose, an upper portion of the structure may be removed, for example, by CMP, to expose the upper surface of the highest metallization level 45 in the structure.

FIG. 1H illustrates a step of forming of a heat-sensitive component 51 on the upper surface of the structure illustrated in FIG. 1G.

The heat-sensitive component comprises, for example: a quantum film (QF) of a photosensitive detector; and/or a layer of a phase-change material, for example for a memory cell of “Phase Change Memory” (PCM) type, such as GST (Germanium Ge, Antimony Sb, Tellurium Te), or any other element made of a material likely to be degraded under the effect of heat. As an example, it is considered that a component is heat-sensitive if it is degraded, or if one of its characteristics is degraded, under a temperature, for example higher than 150° C., for example higher than 200° C.

As an example, component 51 comprises an active layer 53, for example made of a heat-sensitive material, a lower electrode 55, and an upper electrode 57. As an example, lower electrode 55 is coupled to a metallization level 45, for example, by means of a via. Electrode 55 is formed, for example, on top of and in contact with the upper surface of the structure illustrated in FIG. 1G, for example the upper surface of stack 43. Lower electrode 55 is for example local, that is, at the end of its forming method, it does not cover the entire upper surface of the structure. As an example, electrode 55 is formed by a local deposition method. As a variant, lower electrode 55 is formed in full wafer fashion and then locally removed.

Active layer 53 is formed, for example, in full wafer fashion, that is it covers the entire upper surface of lower electrode 55 and the surface of stack 43 not covered with electrode 55. As an example, active layer 53 is formed, for example, on top of and in contact with the above-mentioned layers.

Upper electrode 57 is formed, for example, in full wafer fashion on the upper surface of active layer 53.

FIG. 1I illustrates a step of forming of a contact 61 on the upper surface of the structure illustrated in FIG. 1H.

During this step, a portion of active layer 51 and the upper electrode 57 of heat-sensitive element 51 are, in a first phase, removed to only be kept locally. More particularly, upper electrode 57 and active layer 53 are locally removed to only be kept in the vicinity of lower electrode 55.

At the end of the step of removal of a portion of element 51, an insulating layer 59 is formed, for example in full wafer fashion, at the surface of the structure. Insulating layer 59 is thus formed on top of and in contact with heat-sensitive element 51 and on top of and in contact with stack 43 when the latter is not covered with element 51. As an example, layer 59 comprises a plurality of sub-layers, for example two sub-layers 59a and 59b.

As an example, layer 59 is made of one or a plurality of dielectric materials. As an example, layer 59 comprises sub-layer 59a, for example made of silicon nitride (SiN), and sub-layer 59b, formed on top of and in contact with sub-layer 59a, for example made of silicon oxynitride (SiON). As an example, sub-layer 59a is formed on top of and in contact with the upper surface of element 51, in contact with the sides of element 51, and on top of and in contact with stack 43 when the latter is not covered with element 51.

After the deposition of layer 59, contact 61 is formed. Contact 61 is formed, for example, by deposition of a layer on top of and in contact with layer 59 and, for example, in openings 63 previously formed in layer 59.

As an example, one or a plurality of openings 63 are formed in front of certain metallization levels 45 flush with the upper surface of stack 43. These openings 63 emerge, for example, onto the upper surface of levels 45.

As an example, one or a plurality of openings 63 are further formed in front of element 51. These openings 63 emerge, for example, onto the upper surface of element 51.

Layer 61 is formed, for example, conformally at the surface of the structure, that is, it is formed with a constant thickness. As an example, layer 61 is formed locally and more particularly inside and in the vicinity of openings 63. As a variant, layer 61 is formed in full wafer fashion and is then locally removed to only be kept inside and in the vicinity of openings 63.

As an example, layer 61 is formed so that it is uninterrupted between all the openings 63. As an example, layer 61 is made of a metallic material, for example made of aluminum. As an example, layer 61 is formed at low temperature, that is at a temperature lower than 400° C., for example lower than 200° C., for example lower than 150° C.

FIG. 1J illustrates a structure obtained at the end of a step of deposition of an insulating layer 65 and a planarizing layer 67 on the upper surface of the structure illustrated in FIG. 1I.

More particularly, during this step, layers 61 and 59 are covered with layer 65. As an example, layer 65 is an insulating layer, for example made of a dielectric material, for example made of silicon nitride or silicon oxynitride.

The deposition of layer 65 is followed, for example, by a deposition of planarizing layer 67. As an example, layer 67 is deposited in full wafer fashion at the surface of the structure and more particularly on top of and in contact with layer 65. Layer 67 is, for example, made of a dielectric, for example made of an oxide, for example made of silicon oxide.

FIG. 1K illustrates a structure obtained at the end of a step of transfer of a handle 64 onto the structure illustrated in FIG. 1J.

As an example, during this step, handle 64 is transferred on top of and in contact with layer 67 via an adhesive layer 69.

Substrate 67 is, for example, made of a semiconductor material, for example made of silicon. As an example, substrate 67 comprises no active element and it is referred to in the art as a passive handle.

FIG. 1L illustrates a structure obtained at the end of a step of removal of substrate 31 from the structure illustrated in FIG. 1K.

During this step, a portion of substrate 31 is removed, for example, by grinding. A wet etching step follows, for example, the grinding step. This step enables to complete the removal of substrate 31 from the entire surface. The wet etching is stopped, for example, in the stop layer 33, before reaching layer 35. As an alternative example, stop layer 33 is omitted, and then layer 35 is thus in direct contact with substrate 31 and the etch step is temporally controlled to stop on the lower surface of layer 35.

As an example, pads 37 are then exposed by removing the portion of layer 41 located on the lower surface side of pads 37 and, when it is present, stop layer 33. For this purpose, a chemical mechanical polishing may be implemented. At the end of this step, the lower surface of pads 37 is flush with the lower surface of layer 35. Barrier layer 41 remains present only on the sides of pads 37.

At the end of this step, the rear surface of the structure is hybrid, that is, it is formed of metallic materials forming pads 37 and of amorphous silicon forming layer 35.

The structure obtained at the end of this step corresponds to the second structure of the assembly. In the rest of the disclosure, the upper surface of this structure is considered in the orientation of FIG. 1L as being the front side and the lower surface of this structure in the orientation of FIG. 1L as being the back side.

FIGS. 1M to 1P are successive steps of a method of assembly of first and second structures of the assembly.

FIG. 1M illustrates a step of activation of the contact surfaces of the structures of FIGS. 1C and 1L and of their alignment for the bonding.

As an example, during this step, the bonding surfaces, and more precisely the back side of the structure illustrated in FIG. 1L and the front side of the structure illustrated in FIG. 1C, are activated in a first phase.

The activation of the surfaces is performed, for example, by an etching or ion abrasion method comprising sending onto the surfaces to be activated a beam of ions or atoms, for example neutral. The beam enables to remove, for example, possible oxides at the surface of the surfaces to be activated and to form dangling bonds which will be used to form covalent bonds during the placing into contact, at a subsequent step, of the activated surfaces. Such a method allows a bonding generally referred to in the art as surface-activated bonding (SAB).

This step is performed, for example, under vacuum, that is at a pressure lower than the atmospheric pressure, and for example at ambient temperature.

In FIG. 1M, the structure of FIG. 1L is shown in an upper portion and the structure of FIG. 1C is shown in a lower portion.

In a second phase, the lower surface or back side of the structure illustrated in FIG. 1L is aligned with the upper surface or front side of the structure illustrated in FIG. 1C. More particularly, the pads 37 of the structure illustrated in FIG. 1L and the pads 19 of the structure illustrated in FIG. 1C are aligned.

FIG. 1N illustrates a step of placing into contact of the two structures illustrated in FIG. 1M.

During the placing into contact, pads 19 contact with pads 37 and layer 25 contacts with layer 35. It is referred to in the art as a hybrid bonding.

As an example, this step is performed with no rupture of vacuum after the activation step. The step of placing into contact is, for example, carried out in the chamber where the activation has been performed.

The step of placing into contact is, for example, followed by an anneal step. As an example, the anneal is performed for at most 2 hours, for example, for at most 1 hour. As an example, the anneal is performed at a temperature in the range from 50° C. to 200° C., for example on the order of 150° C. The anneal allows, in addition to strengthening the bonding, the diffusion of the silicon atoms of layer 25 located at the interface between pads 19 and pads 37 into pads 19 and 37. It is referred to in the art as a phenomenon of solubilization of the silicon in copper.

FIG. 1O illustrates a structure obtained at the end of a step of flipping of the structure illustrated in FIG. 1N.

FIG. 1P illustrates a structure obtained at the end of a step of forming of a contact 71 on the upper surface of the structure illustrated in FIG. 1O.

During this step, substrate 11 is, for example, locally etched to create an opening emerging onto the upper surface of stack 13. Then, a depositing, in front thereof, of a conductive layer is made. The layer is, for example, made of a metallic material, for example made of aluminum.

The layer forming contact 71 is, for example, deposited by a method at low temperature, for example at a temperature lower than 150° C.

As an example, prior to the step of etching of substrate 11, the latter is thinned, for example by a chemical mechanical or mechanical method.

An advantage of the first embodiment is that it is compatible with the assembly of structures comprising heat-sensitive elements, the steps of bonding or of forming of metal elements being carried out at temperatures lower than 400° C., for example, lower than 150° C.

Another advantage of the present embodiment is that it allows a high-quality silicon-on-silicon assembly since, on one of the two structures, the silicon is deposited while, on the second structure, the silicon corresponds to the silicon of the initial substrate.

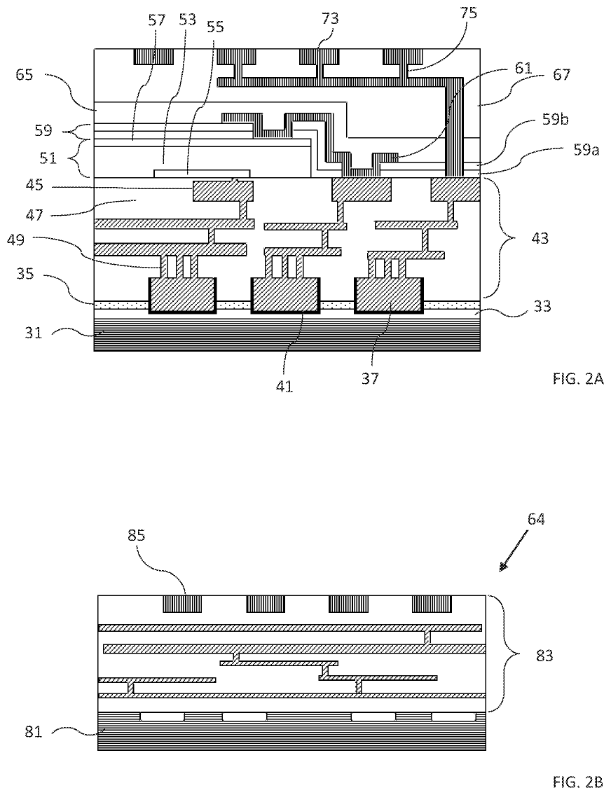

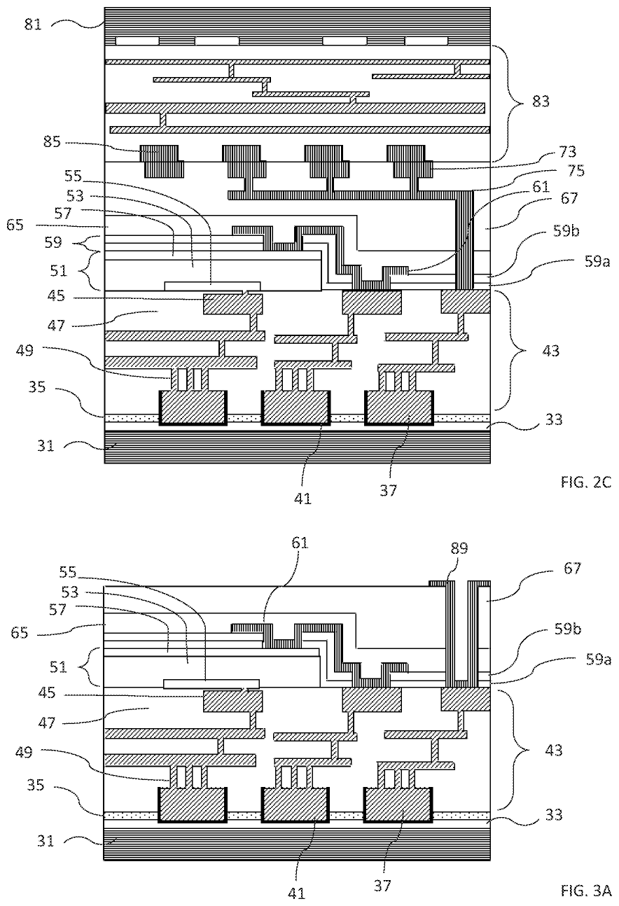

FIGS. 2A to 2C show steps of a method of assembly according to a second embodiment.

More particularly, the second embodiment differs from the first embodiment in that handle 64 is active and is connected to metallization levels 45 via metal contacts 73 and via 75.

The second embodiment differs from the first embodiment from the step of transfer of handle 64, the assembly method according to the second embodiment thus starts with the steps shown in FIGS. 1A to 1J, which will not be described again hereafter.

FIG. 2A illustrates a structure obtained at the end of a step of forming of contacts 73 and via 75 in the layer 67 of the structure illustrated in FIG. 1J.

During this step, in a first phase, openings are formed in layer 67 to form contacts 73. As an example, during this step, an opening is also formed in front of one of the metallization levels 45 flush with the upper surface of stack 43 and emerging onto a level 45, in layer 67, layer 65, and layer 59 so as to form via 75.

In a second phase, the openings are filled. Contacts 73 and via 75 are, for example, made of a material allowing the filling of the openings at low temperature, that is at a temperature lower than 400° C., for example lower than 150° C. As an example, contacts 73 and via 75 are made of a metallic material, for example based on aluminum.

Contacts 73 are, for example, flush with the upper surface of layer 67. As an example, contacts 73 are connected to metallization levels 45 by means of via 75.

FIG. 2B illustrates a structure of active handle 64, referred to as functionalized or comprising a logic circuit. Handle 64 comprises, for example, a substrate 81 having an interconnection network 83 formed thereon. As an example, network 83 corresponds to a stack of conductive tracks and insulating layers, the conductive tracks being coupled together by conductive vias. As an example, the tracks and the vias of network 83 are made of a metallic material, for example based on copper. As an example, the insulating layers of network 83 are made of a dielectric material, for example made of silicon dioxide. As an example, handle 64 comprises, above network 83, in the orientation of FIG. 2B, that is opposite to substrate 81, contacts 85. As an example, contacts 85 are formed in an upper insulating layer of network 83, so that they are flush with the upper surface of handle 64. As an example, contacts 85 are made of a metallic material, for example based on aluminum. As an example, contacts 85 are made of the same material as the contacts 73 illustrated in FIG. 2A. As an example, the number of contacts 73 is similar to the number of contacts 85 and the arrangement of contacts 85 on the upper surface of handle 64 is, for example, symmetrical to the arrangement of contacts 73 at the surface of layer 67.

FIG. 2C illustrates a structure obtained at the end of a step of assembly of the structures illustrated in FIGS. 2A and 2B.

Before the placing into contact of the two structures, the surfaces of the structures which will be placed into contact are, for example, activated. Thus, the upper surface of FIG. 2A and the upper surface of FIG. 2B are activated.

The activation of the surfaces is performed, for example, by an etching or ion abrasion method as described in relation with FIG. 1M.

As an example, the assembly step comprises, after the activation, the placing into contact of the structure illustrated in FIG. 2A and of the structure illustrated in FIG. 2B and more particularly, of the two activated surfaces. During this step, the structure illustrated in FIG. 2B is then flipped. In FIG. 2C, the structure of FIG. 2A is shown in a lower portion and the structure of FIG. 2B is shown in an upper portion.

During this step, in addition to the placing into contact, the two structures are aligned and, more particularly, contacts 73 are aligned with contacts 85. Contacts 85 and 73 being, for example, made of the same material, it is referred to as a hybrid assembly. This step is, for example, carried out at ambient temperature, for example at a temperature lower than 150° C.

As an example, this step is carried out with no rupture of vacuum after the activation step. The step of placing into contact is, for example, carried out in the chamber where the activation has been performed.

The structure illustrated in FIG. 2C corresponds to the second structure of the assembly according to the second embodiment. It may, after the above-described steps, be assembled to the structure illustrated in FIG. 1C similarly to what has been described for the first embodiment in relation with FIGS. 1L to 1P. In the second embodiment, it is referred to as an assembly of three structures (the structures of FIGS. 2A, 2B, and 1C) and thus of a 3D assembly.

An advantage of the present embodiment is that it allows the assembly of more than two structures with no need to use a through silicon via (TSV).

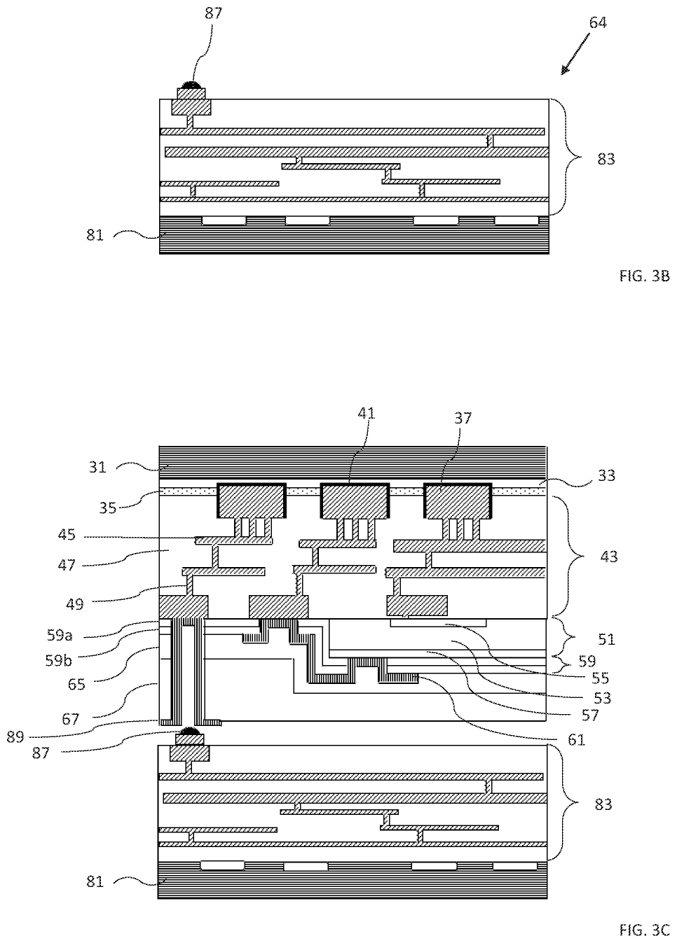

FIGS. 3A to 3C show steps of an assembly method according to a third embodiment.

More particularly, the third embodiment differs from the first embodiment in that handle 64 is active and is connected to metallization level 45 via bosses 87.

The third embodiment differs from the first embodiment from the step of transfer of handle 64, the assembly method according to the third embodiment thus starts with the steps of FIGS. 1A to 1J, which will not be described again hereafter.

FIG. 3A illustrates a structure obtained at the end of a step of forming of a contact 89 in the layer 67 of the structure illustrated in FIG. 1J.

During this step, an opening is formed, for example, in a first phase in front of at least one metallization level 45, flush with the upper surface of stack 43. This opening is formed, for example, from the upper surface of layer 67 and emerges onto the considered level 45. The opening thus crosses, for example, layer 67, layer 65, and layer 59.

In a second phase, the material is deposited, for example, in the opening and more particularly on the sides and in the bottom of the opening to form a contact recovery contact 89. As an example, contact 89 further extends around the opening, on the upper surface of layer 67.

Contact 89 is, for example, made of a material capable of being deposited at low temperature, that is at a temperature lower than 400° C., for example lower than 150° C. As an example, contact 89 is made of a conductive material, for example made of a metallic material, for example based on aluminum. As an example, the material forming contact 89 is deposited in full wafer fashion, for example conformally, and then is removed locally to only be kept in the vicinity of the opening and thus form contact 89. Thus, at the end of this step, the upper surface of layer 67 is exposed.

FIG. 3B illustrates a structure of handle 64. The handle 64 illustrated in FIG. 3B is similar to the handle 64 illustrated in FIG. 2B, with the difference that it comprises boss 87 on its upper surface. Boss 87 is, for example, coupled to network 83 and is, for example, made of the same material as network 83. As an example, boss 87 is made of a conductive material, for example a metallic material. In FIG. 3B, only a single boss 89 has been shown, however, in practice, handle 64 may comprise a plurality of bosses 87.

FIG. 3C illustrates a structure obtained at the end of a step of assembly of the structures illustrated in FIGS. 3A and 3B.

During this step, the structures illustrated in FIGS. 3A and 3B, and more particularly the upper surfaces of the structures illustrated in FIGS. 3A and 3B, are placed into contact to align boss 87 and contact 89.

In FIG. 3C, the structure of FIG. 3A is shown in an upper portion and the structure of FIG. 3B is shown in a lower portion.

As an example, the bonding of the two structures is ensured by an adhesive or glue layer.

If the handle comprises a plurality of bosses 87, each of bosses 87 will then be aligned with a contact 89 during the placing into contact of the two structures.

The structure illustrated in FIG. 3C corresponds to the second structure of the assembly according to the third embodiment. It may, after the above-described steps, be assembled to the structure illustrated in FIG. 1C similarly to what has been described for the first embodiment in relation with FIGS. 1L to 1P.

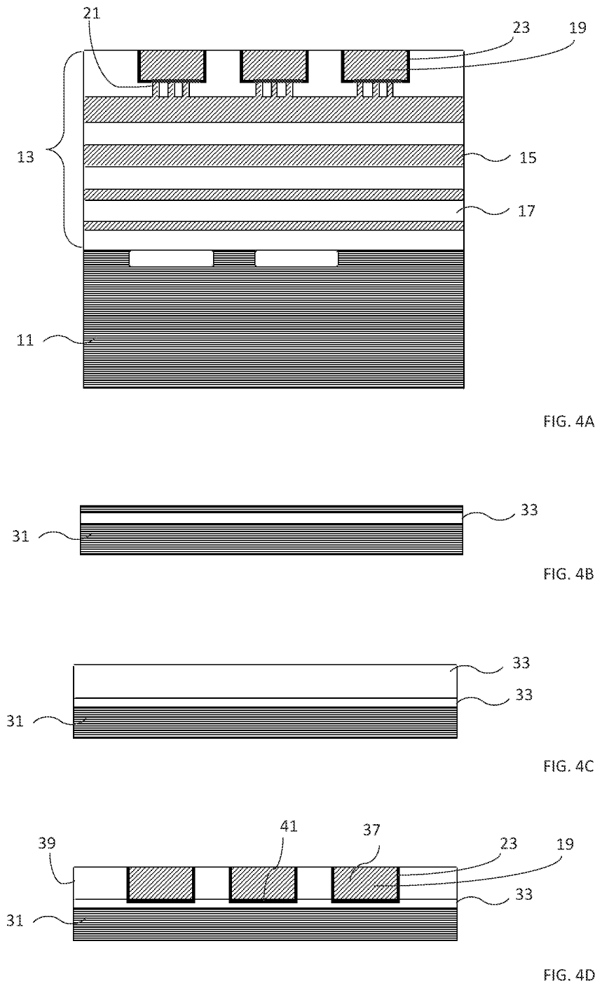

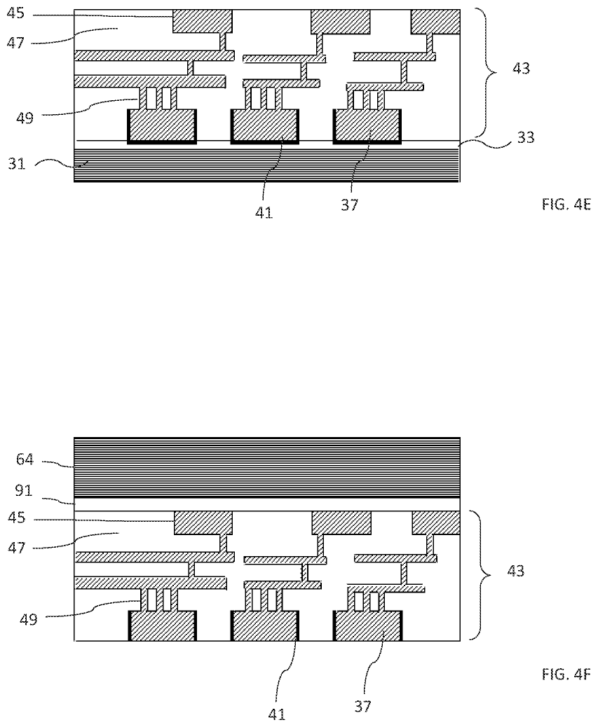

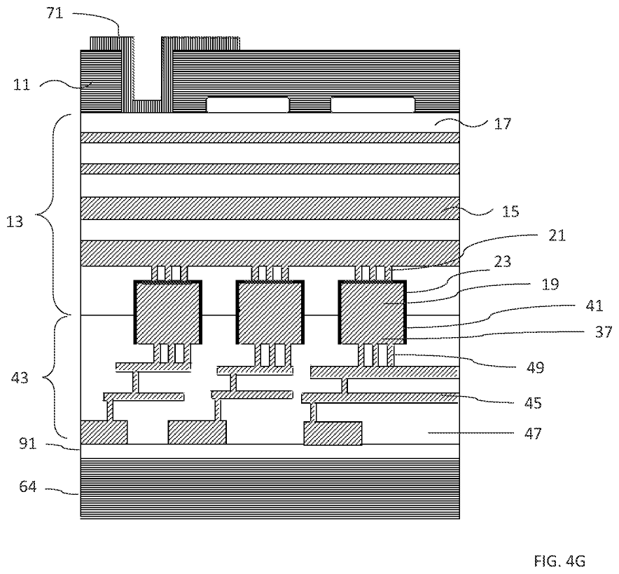

FIGS. 4A to 4G show steps of an assembly method according to a fourth embodiment.

More particularly, the fourth embodiment differs from the first embodiment in that the structures targeted by the assembly comprise no heat-sensitive element.

FIG. 4A illustrates the first structure of the assembly, identical to the structure illustrated in FIG. 1B. In this embodiment, the first structure of the assembly comprises no layer 25 on its upper surface, contacts 23 are thus flush with the upper surface of this structure.

In the rest of the description, it is considered that the upper surface of this structure corresponds to its front side and the lower surface of this structure corresponds to its back side.

FIGS. 4B to 4F are successive steps of a method of forming of the second structure of the assembly, different from the first structure of the assembly.

FIG. 4B illustrates an initial structure identical to the structure illustrated in FIG. 1D.

FIGS. 4C and 4D illustrate structures obtained at the end of respective steps of deposition of layer 39 and of forming of pads 37 similarly to what has been described in relation with FIG. 1F. The above-mentioned steps however differ from what has been described in relation with FIG. 1F by the fact that layer 35 is omitted, layer 39 being then directly formed on top of and/or inside of substrate 31, for example on top of and in contact with stop layer 33. As an example, pads 37 are formed so that they are buried in layer 33 by a few nanometers, for example on the order of 2 nm.

FIG. 4E illustrates a structure obtained at the end of a step of forming of stack 43 on the upper surface of the structure illustrated in FIG. 1D similarly to what has been described in relation with FIG. 1G.

FIG. 4F illustrates a structure obtained at the end of a step of transfer of handle 64 onto the upper surface of the structure illustrated in FIG. 4E and of removal of substrate 31. These steps are, for example, similar to the steps of transfer of handle 64 and removal of substrate 31 described in relation with FIGS. 1K and 1L, with the difference that handle 64 is directly deposited on stack 43. As an example, handle 64 is deposited on the upper surface of stack 43, for example, via an adhesive layer 91. At the end of the steps of FIG. 4F, pads 37 are surrounded with barrier layer 41 on their sides only, the barrier layer 41 covering the lower surface of pads 37 in FIG. 4E being removed. Thus, at this stage, the lower surface of pads 37 is flush with the lower surface of interconnection stack 43.

As an example, in the structure illustrated in FIG. 4F, stack 43 has a thickness smaller than 5 μm, for example, in the range from 1 μm to 2 μm.

At the end of this step, the structure corresponds to the second structure of the assembly according to the fourth embodiment. In the rest of the description, the upper surface of this structure in the orientation of FIG. 4F is considered as being the front side and the lower surface of this structure in the orientation of FIG. 4F is considered as being the back side.

It may, after the above-described steps, be assembled to the first structure of the assembly illustrated in FIG. 4A.

FIG. 4G illustrates a structure obtained at the end of a step of assembly of the first assembly structure illustrated in FIG. 4A with the second assembly structure illustrated in FIG. 4F. During this step, the two structures are assembled so that the front side of the structure illustrated in FIG. 4A faces the back side of the structure illustrated in FIG. 4F. In FIG. 4G, the structure of FIG. 4A is shown in an upper portion and the structure of FIG. 4F is shown in a lower portion.

The assembly step is preceded, for example, by a step of activation of the surfaces placed in contact as described in relation with FIG. 1M. The lower surface of the structure illustrated in FIG. 4A and the lower surface of the structure illustrated in FIG. 4F are then here more particularly activated.

At the end of the assembly step, a contact 71 may, for example, be formed in substrate 11 and substrate 11 may, for example, be thinned similarly to what has been described in relation with FIG. 1P.

Various embodiments and variants have been described. Those skilled in the art will understand that certain features of these various embodiments and variants may be combined, and other variants will occur to those skilled in the art. In particular, although the fourth embodiment has been described with an inactive handle, it may be combined with each of the second and third embodiments where the handles are active. Further, the described embodiments are for example not limited to the examples of dimensions and of materials mentioned hereabove.

Finally, the practical implementation of the described embodiments and variations is within the abilities of those skilled in the art based on the functional indications given hereabove.

1. A method of assembly of first and second wafers by bonding, comprising the steps of:
a) forming a first wafer comprising a first semiconductor layer and first metal contacts on a side of a first surface of the first semiconductor layer;
b) forming a second wafer comprising a second semiconductor layer, an amorphous silicon layer or a dielectric material layer over a first surface of the second semiconductor layer, and second metal contacts over the first surface of the second semiconductor layer, wherein said second metal contacts are formed in said amorphous silicon layer or dielectric material layer;
c) after step b), transfer and bonding a handle onto a surface of the second wafer opposite to the second semiconductor layer;
d) after step c), entirely removing the second semiconductor layer to expose the second metal contacts and said amorphous silicon layer or dielectric material layer; and
e) after steps a) and d), bonding the first and second wafers to each other to electrically connect the first metal contacts to the second metal contacts.

2. The method according to claim 1, comprising between steps a) and e), a step of activating the surface of the first metal contacts opposite to the first semiconductor layer and between steps d) and e), a step of activating a surface of the second metal contacts exposed during step d).

3. The method according to claim 2, wherein the activating steps are carried out during a same step, under vacuum in a same activation chamber.

4. The method according to claim 3, wherein step e) is carried out under vacuum, with no rupture of vacuum with the activating steps.

5. The method according to claim 1, comprising, between steps b) and c), a step f) of forming a heat-sensitive element on the second wafer.

6. The method according to claim 1, comprising, after step a), a step g) forming a further amorphous silicon layer on the first metal contacts.

7. The method according to claim 1, wherein said second metal contacts extend completely through said amorphous silicon layer or dielectric material layer.

8. The method according to claim 1, wherein the handle is inactive.

9. The method according to claim 1, wherein the handle is active and comprises a logic circuit.

10. The method according to claim 9, wherein step c) bonding the handle comprises performing a surface-activated bonding of the handle to the second wafer.

11. The method according to claim 9, wherein step c) bonding the handle comprises using an adhesive layer to bond the handle to the second wafer.

12. The method according to claim 11, further comprising forming an electric contact including at least one boss in the handle.

13. A method of assembly of first and second wafers by bonding, comprising the steps of:
a) forming a first wafer comprising a first semiconductor layer and first metal contacts on a side of a first surface of the first semiconductor layer;
b) forming a second wafer comprising a second semiconductor layer, a stack of an amorphous silicon layer and a dielectric material layer over a first surface of the second semiconductor layer, and second metal contacts over the first surface of the second semiconductor layer, wherein said second metal contacts are formed extending through stack of the amorphous silicon layer and dielectric material layer;
c) after step b), transfer and bonding a handle onto a surface of the second wafer opposite to the second semiconductor layer;
d) after step c), entirely removing the second semiconductor layer to expose the second metal contacts and said amorphous silicon layer; and
e) after steps a) and d), bonding the first and second wafers to each other to electrically connect the first metal contacts to the second metal contacts.

14. The method according to claim 13, comprising between steps a) and e), a step of activating the surface of the first metal contacts opposite to the first semiconductor layer and between steps d) and e), a step of activating a surface of the second metal contacts exposed during step d).

15. The method according to claim 14, wherein the activating steps are carried out during a same step, under vacuum in a same activation chamber, and wherein step e) is carried out under vacuum, with no rupture of vacuum with the activating steps.

16. The method according to claim 13, comprising, between steps b) and c), a step f) of forming a heat-sensitive element on the second wafer.

17. The method according to claim 16, wherein the handle is active and comprises a logic circuit, and wherein step c) bonding the handle comprises performing a surface-activated bonding of the handle to the second wafer.

18. The method according to claim 16, wherein step c) bonding the handle comprises using an adhesive layer to bond the handle to the second wafer.

19. A method of assembly of first and second wafers by bonding, comprising the steps of:
a) forming a first wafer comprising a first semiconductor layer and first metal contacts on a side of a first surface of the first semiconductor layer;
b) forming a second wafer comprising a second semiconductor layer, a dielectric material layer over a first surface of the second semiconductor layer, and second metal contacts over the first surface of the second semiconductor layer, wherein said second metal contacts are formed extending through said dielectric material layer;
c) after step b), transfer and bonding a handle onto a surface of the second wafer opposite to the second semiconductor layer;
d) after step c), entirely removing the second semiconductor layer to expose the second metal contacts and said dielectric material layer; and
e) after steps a) and d), bonding the first and second wafers to each other to electrically connect the first metal contacts to the second metal contacts.

20. The method according to claim 19, comprising between steps a) and e), a step of activating the surface of the first metal contacts opposite to the first semiconductor layer and between steps d) and e), a step of activating a surface of the second metal contacts exposed during step d).

21. The method according to claim 20, wherein the activating steps are carried out during a same step, under vacuum in a same activation chamber, and wherein step e) is carried out under vacuum, with no rupture of vacuum with the activating steps.

22. The method according to claim 19, comprising, between steps b) and c), a step f) of forming a heat-sensitive element on the second wafer.

23. The method according to claim 22, wherein the handle is active and comprises a logic circuit, and wherein step c) bonding the handle comprises performing a surface-activated bonding of the handle to the second wafer.

24. The method according to claim 22, wherein step c) bonding the handle comprises using an adhesive layer to bond the handle to the second wafer.
